(19) United States
(12) Patent Application Publication
(10) Pub. No.: US 2003/0173614 A1
(43) Pub. Date: Sep. 18, 2003

(54) Semiconductor integrated circuit device and manufacturing method thereof

(75) Inventors: Yoshitaka Nakamura, Tokyo (JP); Isamu Asano, Tokyo (JP); Shinpei Iijima, Tokyo (JP); Masahiko Hiratani, Akishima (JP); Hiroshi Sakuma, Tokyo (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/352,133

(22) Filed: Jan. 28, 2003

(30) Foreign Application Priority Data
Jan. 28, 2002 (JP) 2002-19159

(51) Int. Cl. H01L 29/76; H01L 29/94; H01L 27/108; H01L 21/8242; H01L 31/119

(52) U.S. Cl. 257/310; 438/240; 438/241; 438/242

(57) ABSTRACT

Disclosed are a semiconductor integrated circuit device and a method of manufacturing the same capable of improving the characteristics of the semiconductor integrated circuit device by reducing a leakage current of a capacitor used in a DRAM memory cell. A data storage capacitor connected to a data transfer MISFET in a memory cell forming area via plugs is formed in the following manner. That is, a lower electrode composed of an Ru film is formed in a hole in a silicon oxide film, and then, a tantalum oxide film is deposited on the lower electrode. Thereafter, a first thermal treatment in an oxidizing atmosphere is performed to the film at a temperature sufficient to repair an oxygen defect and having no influence on the materials below the tantalum oxide film. Further, a second thermal treatment in an inactive atmosphere is performed at a temperature at which the tantalum oxide film is not completely crystallized (650° C.) and higher than that applied in the later process. Thereafter, an upper electrode composed of a laminated film of an Ru film and a W film is formed on the capacitor insulating film made from the tantalum oxide film.

### TECHNICAL FIELD OF THE INVENTION

The present invention relates to a semiconductor integrated circuit device and a manufacturing method thereof. More particularly, the present invention relates to a technique effectively applied to a capacitor used in a memory cell such as a DRAM (Dynamic Random Access Memory).

### BACKGROUND OF THE INVENTION

A DRAM is provided with a data transfer MISFET (Metal Insulator Semiconductor Field Effect Transistor) and a data storage capacitor connected in series to the MISFET. The data storage capacitor is formed by sequentially depositing, for example, silicon to be a lower electrode, tantalum oxide to be a capacitor insulating film, and a refractory metal film to be an upper electrode.

However, in the case where silicon is used as the lower electrode, a silicon oxide film is formed at the interface between the silicon and tantalum oxide formed on the silicon when performing a thermal treatment for the crystallization and the improvement of the film quality of the tantalum oxide. Therefore, since the tantalum oxide and the silicon oxide film function as dielectrics, it is difficult to achieve the high dielectric constant.

The inventors of this invention have been conducting the research and development for the lower electrode materials constituting a data storage capacitor, and examinations for the use of ruthenium (Ru) as the lower electrode material have been carried out to solve the above-described problems.

It is believed that, since Ru rarely forms a low dielectric constant film such as an oxide film and Ru is a metal, it is possible to sufficiently reduce the parasitic resistance of the electrode even if the film made of Ru is thinly formed. For example, in pp. 162 to 163 in ICSSDM (International Conference on Solid State Devices and Materials) 1999, a capacitor of a DRAM using ruthenium as a material of the upper and lower electrodes and tantalum oxide as a material of a capacitor insulating film is described, in which the dielectric constant in the annealing of tantalum oxide at a temperature 650° C. or lower is 32 and that at a temperature about 700° C. is 60.

In addition, descriptions about the improvement of the film quality of an oxide film used as a dielectric film of a capacitor are found in the gazette of the Japanese Patent Laid-Open No. 10-229080, in which disclosed is a technique for improving the insulation of an oxide by depositing an amorphous oxide film such as a Ta₂O₅ film by a low-pressure CVD and then performing a thermal treatment in an ozone-containing atmosphere under an atmospheric pressure at a temperature of 300 to 500° C., more preferably, 350 to 450° C.

### SUMMARY OF THE INVENTION

However, as a result of the examination of the use of an Ru film as a lower electrode by the inventors of this invention, a phenomenon such as the increase of the leakage current is observed.

With regard to the leakage current, in the case where silicon is used as a lower electrode, the leakage current can be kept small since a silicon oxide film is formed at the interface between the silicon and the tantalum oxide as described above.

However, in the case where Ru is used as a lower electrode, although the dielectric constant is improved since the silicon oxide film is rarely formed, the quality of the tantalum oxide film constituting the capacitor largely influences the leakage current.

As a result of the further examination by the inventors based on the analysis as described above, it is found out that the crystal state of the tantalum oxide film and the state of the interface between the tantalum oxide film and the lower electrode largely influence the leakage current as described later in detail.

An object of the present invention is to provide a technique capable of reducing the leakage current in a capacitor.

Another object of the present invention is to provide a technique capable of improving the characteristics of a capacitor by reducing the leakage current and thus improving the characteristics of a semiconductor integrated circuit device having the capacitor.

The above and other objects and novel characteristics of the present invention will be apparent from the description and the accompanying drawings of this specification.

The typical ones of the inventions disclosed in this application will be briefly described as follows.

(1) The semiconductor integrated circuit device according to the present invention is characterized in that a grain boundary of the conductive material grains constituting a lower electrode exists in a lower electrode of a semiconductor integrated circuit device having a capacitor, however, a grain boundary of material grains constituting a dielectric film, which penetrates the dielectric film, does not exist in a part of the dielectric film corresponding to the grain boundary in the lower electrode. Also, the grain boundary extending from the edge portion of the grain boundary in the lower electrode does not exist in the dielectric film.

(2) Also, a tantalum oxide film with a microcrystalline structure or an incompletely crystallized tantalum oxide film to be a dielectric film exists on a position corresponding to that of the grain boundary in the lower electrode. The leakage current of the capacitor under predetermined conditions is 2×10⁻⁸ A/cm² or smaller.

(3) The method of manufacturing a semiconductor integrated circuit device according to the present invention comprises the steps of: (a) forming a lower electrode; (b) forming a dielectric film on the lower electrode; (c) performing a first thermal treatment to the dielectric film in an oxidizing atmosphere; (d) performing a second thermal treatment to the dielectric film in an inactive atmosphere; (e) forming an upper electrode on the dielectric film; and (f) after the step (d), performing a third thermal treatment.

A temperature in the second thermal treatment in the step (d) is higher than that in the third thermal temperature in the step (f). For example, the dielectric film composed of, for example, a tantalum oxide film is in an amorphous state at the time of the deposition and also it is not completely crystallized even after the step (f). Also, the phase of the crystal constituting the dielectric film is changed after the second thermal treatment in the step (d).

Furthermore, the first thermal treatment in the step (c) is performed in, for example, the ozone atmosphere at 250 to 420° C. The second thermal treatment in the step (d) is performed in, for example, the nitrogen atmosphere at 450 to 650° C. The third thermal treatment in the step (f) is performed at 450° C. or lower.

### BRIEF DESCRIPTIONS OF THE DRAWINGS

FIG. 1 is a sectional view of the principal part of a substrate showing the method of manufacturing a semiconductor integrated circuit device according to the first embodiment of the present invention;

FIG. 2 is a sectional view of the principal part of a substrate showing the method of manufacturing a semiconductor integrated circuit device according to the first embodiment of the present invention;

FIG. 3 is a sectional view of the principal part of a substrate showing the method of manufacturing a semiconductor integrated circuit device according to the first embodiment of the present invention;

FIG. 4 is a sectional view of the principal part of a substrate showing the method of manufacturing a semiconductor integrated circuit device according to the first embodiment of the present invention;

FIG. 5 is a sectional view of the principal part of a substrate showing the method of manufacturing a semiconductor integrated circuit device according to the first embodiment of the present invention;

FIG. 6 is a sectional view of the principal part of a substrate showing the method of manufacturing a semiconductor integrated circuit device according to the first embodiment of the present invention;

FIG. 7 is a sectional view of the principal part of a substrate showing the method of manufacturing a semiconductor integrated circuit device according to the first embodiment of the present invention;

FIG. 8 is a sectional view of the principal part of a substrate showing the method of manufacturing a semiconductor integrated circuit device according to the first embodiment of the present invention;

FIG. 9 is a photograph showing a state of a film in the case where a thermal treatment is performed to a laminated film composed of an Ru film and a tantalum oxide film;

FIG. 10 is a diagram schematically showing a state of a film in the case where a thermal treatment is performed to a laminated film composed of an Ru film and a tantalum oxide film;

FIG. 11 is a photograph showing a state of a film in the case where a thermal treatment is performed to a laminated film composed of an Ru film and a tantalum oxide film;

FIG. 12 is a diagram schematically showing a state of a film in the case where a thermal treatment is performed to a laminated film composed of an Ru film and a tantalum oxide film;

FIG. 13 is a photograph showing a state of a film in the case where a thermal treatment is performed to a laminated film composed of an Ru film and a tantalum oxide film;

FIG. 14 is a diagram schematically showing a state of a film in the case where a thermal treatment is performed to a laminated film composed of an Ru film and a tantalum oxide film;

FIG. 15 is a photograph showing a state of a film in the case where a thermal treatment is performed to a laminated film composed of an Ru film and a tantalum oxide film;

FIG. 16 is a diagram schematically showing a state of a film in the case where a thermal treatment is performed to a laminated film composed of an Ru film and a tantalum oxide film;

FIG. 17A is a table showing the relationship between the temperatures used in the first thermal treatment (thermal treatment in an oxidizing atmosphere) and the second thermal treatment (thermal treatment in an inactive atmosphere) and the resultant leakage current before the third thermal treatment, and FIG. 17B is a table showing the relationship between the temperatures used in the first thermal treatment (thermal treatment in an oxidizing atmosphere) and the second thermal treatment (thermal treatment in an inactive atmosphere) and the resultant leakage current after the third thermal treatment;

FIG. 18 is a table showing the relationship between the temperatures used in the first thermal treatment (thermal treatment in an oxidizing atmosphere) and the second thermal treatment (thermal treatment in an inactive atmosphere) and the resultant dielectric constant;

FIG. 19 is a diagram showing a TEG pattern used to obtain the evaluation results shown in FIGS. 17 and 18;

FIG. 20 is a sectional view of the principal part of a substrate showing the method of manufacturing a semiconductor integrated circuit device according to the first embodiment of the present invention;

FIG. 21 is a sectional view of the principal part of a substrate showing the method of manufacturing a semiconductor integrated circuit device according to the first embodiment of the present invention;

FIG. 22 is a sectional view of the principal part of a substrate showing the method of manufacturing a semiconductor integrated circuit device according to the first embodiment of the present invention;

FIG. 23 is a sectional view of the principal part of a substrate showing the method of manufacturing a semiconductor integrated circuit device according to the first embodiment of the present invention;

FIG. 24 is a sectional view of the principal part of a substrate showing the method of manufacturing a semiconductor integrated circuit device according to the first embodiment of the present invention;

FIG. 25 is a sectional view of the principal part of a substrate showing the method of manufacturing a semiconductor integrated circuit device according to the first embodiment of the present invention;

FIG. 26 is a sectional view of the principal part of a substrate showing the method of manufacturing a semiconductor integrated circuit device according to the second embodiment of the present invention;

FIG. 27 is a sectional view of the principal part of a substrate showing the method of manufacturing a semiconductor integrated circuit device according to the second embodiment of the present invention;

FIG. 28 is a sectional view of the principal part of another substrate showing the method of manufacturing a semiconductor integrated circuit device according to the second embodiment of the present invention; and

FIG. 29 is a sectional view of the principal part of another substrate showing the method of manufacturing a semiconductor integrated circuit device according to the second embodiment of the present invention.

### DESCRIPTION OF THE PREFERRED EMBODIMENTS

(First Embodiment)

Hereinafter, embodiments of the present invention will be described with reference to the accompanying drawings. Note that components having the same function are denoted by the same reference symbols throughout the drawings for describing the embodiments, and the repetitive description thereof is omitted.

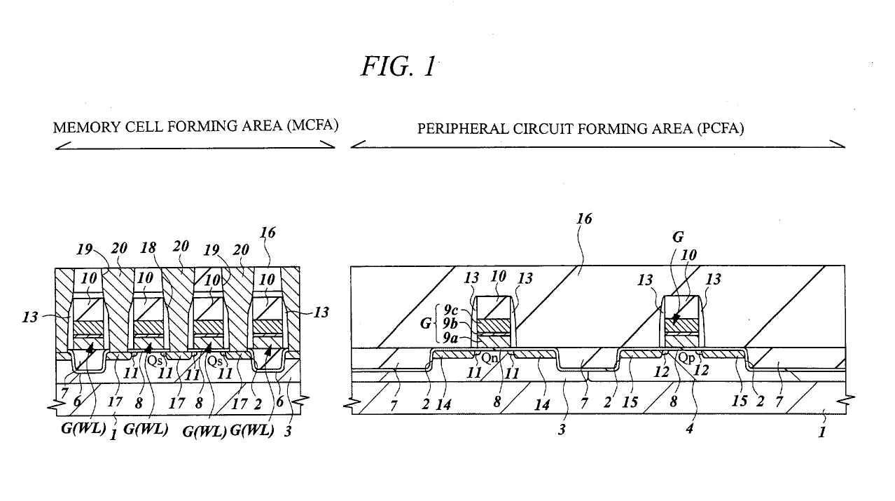

A method of manufacturing a DRAM according to the first embodiment will be described along the process flow with reference to FIGS. 1 to 25. Note that FIGS. 1 to 3 and 21 to 24 are sectional views showing the principal part of a semiconductor substrate, and an area in which a memory cell of a DRAM is to be formed (memory cell forming area (MCFA)) is shown on the left side of each sectional view and an area in which a logic circuit and the like are to be formed (peripheral circuit forming area (PCFA)) is shown on the right side of each sectional view.

A memory cell composed of a data transfer MISFET Qs and a data storage capacitor C is formed in the memory cell forming area, and an n-channel MISFET Qn and a p-channel MISFET Qp for constituting a circuit for driving a memory cell and a logic circuit are formed in the peripheral circuit forming area.

Hereinafter, an example of the process for forming the data transfer MISFET Qs, the n-channel MISFET Qn, and the p-channel MISFET Qp will be described.

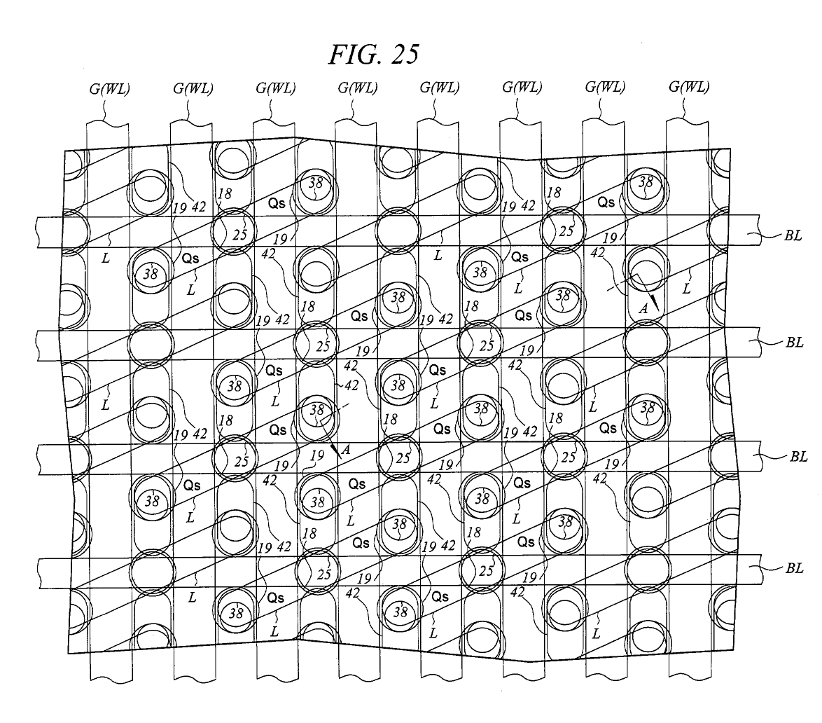

First, as shown in FIG. 1, trenches are formed by performing the etching to a semiconductor substrate (hereinafter, referred to as a substrate) 1, and then, thermal oxidation is performed to form a thin oxide film. Thereafter, an oxide film 7 is filled into the trenches, thereby forming device isolations 2. The formation of the device isolation trench 2 simultaneously forms oval island-shaped active regions (L) surrounded by the device isolation trenches 2 in the memory cell forming area (refer to FIG. 25). Each two data transfer MISFETs Qs sharing either a source or a drain are formed on each of the active regions (L). Also, forming areas for an n-channel MISFET Qn and a p-channel MISFET Qp for constituting a circuit for driving a memory cell and a logic circuit are appropriately defined in the peripheral circuit forming area.

Next, ions of a p-type impurity (for example, boron (B)) and ions of an n-type impurity (for example, phosphorus (P)) are implanted into the substrate 1. Thereafter, a thermal treatment is performed to diffuse these impurities. By doing so, a p-type well 3 is formed in the substrate 1 in the memory cell forming area and a p well 3 and an n well 4 are formed in the substrate 1 in the peripheral circuit forming area.

Next, the surface of the substrate 1 (p-type well 3 and the n-type well 4) is wet-cleaned by the use of a cleaning solution of hydrofluoric acid system. Thereafter, a thermal treatment is performed to form a clean gate oxide film 8 over each surface of the p-type well 3 and the n-type well 4.

Next, a low-resistance polycrystalline silicon film 9a is deposited on the gate oxide film 8 by the CVD (Chemical Vapor Deposition) method. Subsequently, a thin WN (tungsten nitride) film 9b and a W (tungsten) film 9c are deposited on the low-resistance polycrystalline silicon film 9a by the sputtering method, and a silicon nitride film 10 is deposited further thereon by the CVD method.

Next, the silicon nitride film 10, the W film 9c, the WN film 9b and the polycrystalline silicon film 9a are dry-etched with using a photoresist film (not shown) as a mask, thereby forming a gate electrode G. The gate electrode G is composed of the polycrystalline silicon film 9a, the WN film 9b, and the W film 9c. Also, a cap insulating film composed of the silicon nitride film 10 is left on the gate electrode G. Note that the gate electrode G formed in the memory cell forming area functions as a word line WL.

Next, phosphorus (P) ions are implanted into both sides of the gate electrode G over the p-type well 3 in the memory cell forming area and the peripheral circuit forming area, thereby forming an n-type semiconductor region 11. Subsequently, boron fluoride (BF) ions are implanted into both sides of the gate electrode G over the n-type well 4 in the peripheral circuit forming area, thereby forming a p-type semiconductor region 12.

Next, after depositing a silicon nitride film 13 on the substrate 1 by the CVD method, the substrate 1 in the memory cell forming area is covered with a photoresist film (not shown) and an anisotropic etching is performed to the silicon nitride film 13 in the peripheral circuit forming area, thereby forming sidewall spacers on the sidewalls of the gate electrode G in the peripheral circuit forming area.

Next, arsenic (As) ions are implanted into both sides of the gate electrode G over the p-type well 3 in the peripheral circuit forming area, thereby forming n⁺-type semiconductor regions 14 (source and drain). Subsequently, boron fluoride (BF) ions are implanted into both sides of the gate electrode G over the n-type well 4 in the peripheral circuit forming area, thereby forming p⁺-type semiconductor regions 15 (source and drain).

In the process so far, the n-channel MISFET Qn and the p-channel MISFET Qp provided with the source and drain (the n⁻-type semiconductor region 11 and the n⁺-type semiconductor region 14, and the p⁻-type semiconductor region 12 and the p⁺-type semiconductor region 15) having an LDD (Lightly Doped Drain) structure are formed in the peripheral circuit forming area, and the data transfer MISFET Qs composed of the n-channel MISFET is formed in the memory cell forming area.

Next, a silicon oxide film 16 is formed over the gate electrode G and the silicon oxide film 16 on the n⁻-type semiconductor region 11 in the memory cell forming area is dry-etched with using a photoresist film (not shown) as a mask, thereby exposing a surface of the silicon nitride film 13. Thereafter, the exposed silicon nitride film 13 is dry-etched, thereby forming contact holes 18 and 19 on the n⁻-type semiconductor region 11. Then, arsenic (As) ions are implanted through the contact holes 18 and 19, thereby forming an n⁺-type semiconductor region 17.

Next, plugs 20 are formed in the contact holes 18 and 19. The plug 20 is formed in the following manner. That is, a low-resistance polycrystalline silicon film doped with an n-type impurity such as phosphorus (P) is deposited on the silicon oxide film 16 and in the contact holes 18 and 19 by the CVD method. Subsequently, the polycrystalline silicon film is polished by the CMP (Chemical Mechanical Polishing) method to leave the polycrystalline silicon film only in the contact holes 18 and 19. Note that it is also possible to form the n⁺-type semiconductor region 17 by diffusing the n-type impurity in the polycrystalline silicon film.

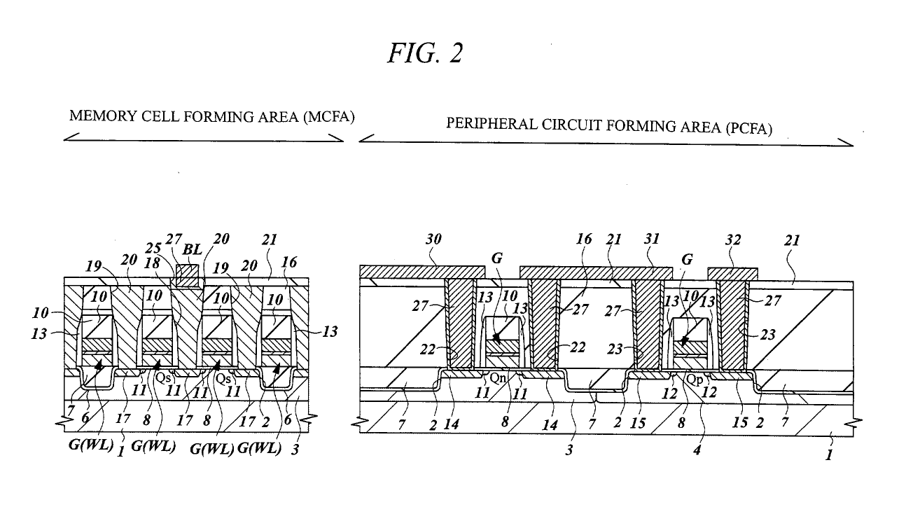

Next, as shown in FIG. 2, a silicon oxide film 21 is deposited on the silicon oxide film 16 by the CVD method. Thereafter, the silicon oxide film 21 in the peripheral circuit forming area and the silicon oxide film 16 below the silicon oxide film 21 are dry-etched with using a photoresist film (not shown) as a mask, thereby forming contact holes 22 on the n⁺-type semiconductor region 14 of the n-channel MISFET Qn and forming contact holes 23 on the p⁺-type semiconductor region 15 of the p-channel MISFET Qp. At the same time, through holes 25 are also formed in the upper part of the plugs 20 in the contact holes 18 in the memory cell forming area.

Next, plugs 27 are formed in the contact holes 22 and 23 and through holes 25. The plug 27 is formed in the following manner. That is, a thin TiN (titanium nitride) film is deposited over the silicon oxide film 21 and in the contact holes 22 and 23 and the through holes 25 by the CVD method. Subsequently, after the deposition of a W film, the W film and the TiN film over the silicon oxide film 21 are polished by the CMP method to leave these films only in the contact holes 22 and 23 and the through holes 25.

Next, a bit line BL is formed on the plug 27 and the silicon oxide film 21 in the memory cell forming area, and first layer wirings 30 to 32 are formed over the silicon oxide film 21 in the peripheral circuit forming area. The bit line BL and the first layer wirings 30 to 32 are formed by, for example, depositing a W film over the silicon oxide film 21 by the sputtering method, and then, performing the dry etching to the W film with using a photoresist film as a mask.

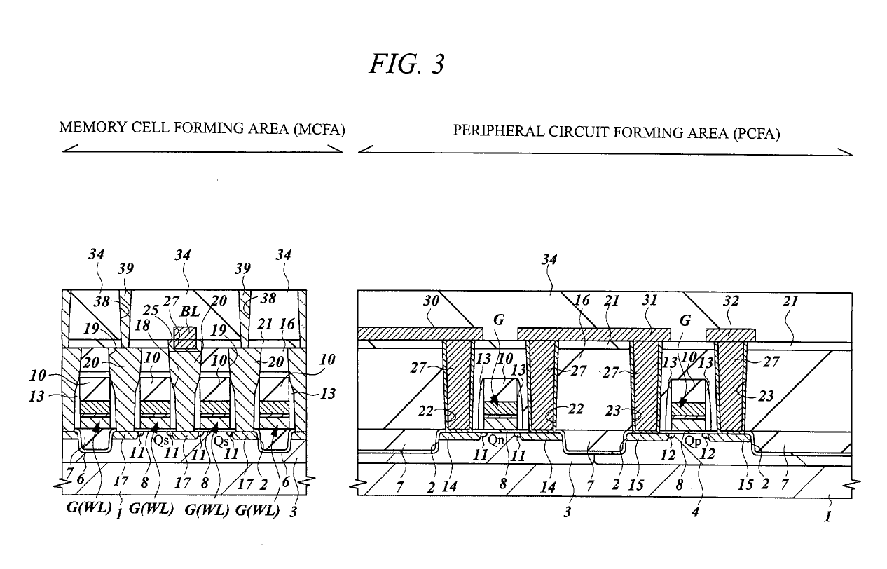

Next, as shown in FIG. 3, a silicon oxide film 34 is deposited over the bit line BL and the first layer wirings 30 to 32 by, for example, the CVD method.

Next, through holes 38 are formed on the plugs 20 in the contact holes 19 by performing the dry etching to the silicon oxide film 34 and the silicon oxide film 21 below the silicon oxide film 34 in the memory cell forming area.

Next, plugs 39 are formed in the through holes 38. The plug 39 is formed in the following manner. That is, a low-resistance polycrystalline silicon film doped with an n-type impurity (for example, phosphorus) is deposited over the silicon oxide film 34 and in the through holes 38 by the CVD method. Thereafter, the polycrystalline silicon film is polished by the CMP method to leave the polycrystalline silicon film only in the through holes 38.

Then, a data storage capacitor C is formed, which is composed of a lower electrode 43a formed of an Ru (ruthenium) film 43, a capacitor insulating film (dielectric film) 44b formed of a tantalum oxide film 44, and an upper electrode 45c formed of a laminated film of an Ru film 45a and a W film 45b.

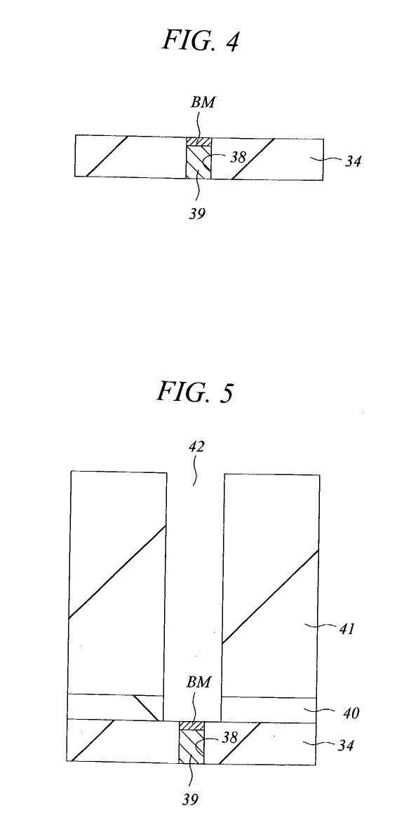

The process of forming the data storage capacitor C will be described in detail with reference to FIGS. 4 to 20. FIGS. 4 to 8 and FIG. 20 schematically show a region in which the data storage capacitor C on the plug 39 is to be formed.

First, as shown in FIG. 4, a barrier metal film BM is formed on a surface of the plug 39. The barrier metal film BM is formed in the following manner. First, the surface of the plug 39 is dented by performing the etching so as to be lower than the surface of the silicon oxide film 34, thereby obtaining a space for filling the barrier metal film BM on the plug 39. Next, a TaN (tantalum nitride) film is deposited over the silicon oxide film 34 by the sputtering method to fill the TaN film in the space formed on the plug 39. Thereafter, the TaN film outside the space is removed by the CMP method (or etchback).

Note that, it is also possible to obtain the space by the over-polishing (over-etching) of the n-type polycrystalline silicon film in the through hole 38 when removing the n-type polycrystalline silicon film outside the through hole 38 by the CMP method (or the etchback) at the time of the formation of the plug 39, more specifically, after depositing the n-type polycrystalline silicon film doped with P over the silicon oxide film 34 by the CVD method to fill the n-type polycrystalline silicon film in the through hole 38.

Subsequently, as shown in FIG. 5, a silicon nitride film 40 with a thickness of about 100 nm is deposited over the silicon oxide film 34 and the barrier metal film BM by the CVD method. Subsequently, a silicon oxide film 41 with a thickness of about 1.4 μm is deposited on the silicon nitride film 40 by the CVD method.

The lower electrode of the data storage capacitor C is formed in the hole (concave portion) formed in the silicon oxide film 41 and the silicon nitride film 40 in the subsequent step. In order to increase the stored charge by increasing the surface area of the lower electrode, it is necessary to deposit the silicon oxide film 41 so as to have a large thickness (in this case, about 1.4 μm). The silicon oxide film 41 is deposited by, for example, the plasma CVD method using oxygen and tetraethoxysilane (TEOS) as source gas. Thereafter, the surface is planarized by the CMP method if necessary.

Next, a hard mask (not shown) composed of a tungsten film and having an opening over the plug 39 is formed on the silicon oxide film 41.

Subsequently, after performing the dry etching to the silicon oxide film 41 with using the hard mask as a mask, the exposed silicon nitride film 40 is dry-etched, thereby forming a deep hole (concave portion) 42. As described above, the silicon nitride film 40 functions as an etching stopper. Also, the surface of the barrier metal film BM in the through hole 38 is exposed at the bottom surface of the deep hole (concave portion) 42.

Subsequently, the hard mask (not shown) left on the silicon oxide film 41 is removed, and then, a thin Ru film (not shown) is formed over the silicon oxide film 41 and in the hole 42 by the sputtering method. By forming such a film, the film formed by the sputtering functions as a seed layer, which makes it possible to efficiently form the later-described Ru film by the CVD method.

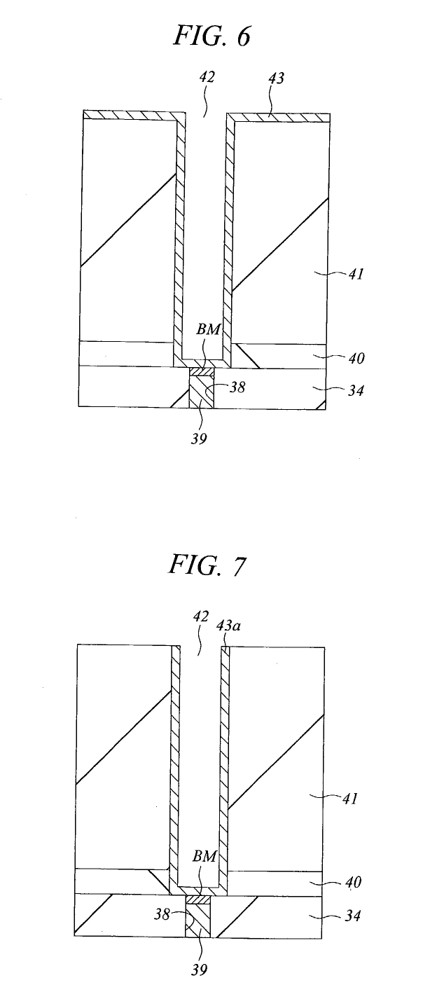

Subsequently, as shown in FIG. 6, an Ru film 43 with a thickness of about 20 nm is formed on the silicon oxide film 41 and in the hole 42 by, for example, the CVD method using ethyl cyclo-pentadienyl ruthenium (Ru (C₂H₅C₅H₄)₂) and O₂ as materials. The Ru film 43 is used as a lower electrode of the data storage capacitor C. As other materials of the lower electrode other than the Ru film, a Pt (platinum) film, an Ir (iridium) film and the like are also available.

Subsequently, a photoresist film (not shown) is coated on the Ru film 43 and the entire surface thereof is exposed and then developed. In this manner, the photoresist film (not shown) is left in the hole 42. The photoresist film is used as a protection film to prevent the removal of the Ru film 43 in the hole 42 (on the sidewall and the bottom surface) when removing the unnecessary Ru film 43 on the silicon oxide film 41 in the next step by the dry etching. Subsequently, dry etching is performed with using the photoresist film as a mask, thereby removing the Ru film 43 on the silicon oxide film 41 and forming the lower electrode 43a. Next, the photoresist film in the hole 42 is removed (FIG. 7).

Note that the barrier metal film BM is formed in order to prevent the undesirable silicide reaction between the Ru film 43 constituting the lower electrode 43a and the polycrystalline silicon constituting the plug 39 in the thermal treatment performed in the course of the manufacturing process described later. Note that it is also possible to use a TiN film, a W film, a WN film, a WSiN film, a TaSiN film, a TiAlN film or a Ta (tantalum) film to form the barrier metal film BM.

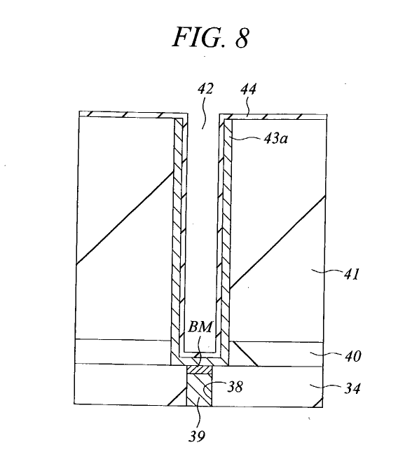

Next, as shown in FIG. 8, a tantalum oxide film 44 to be a capacitor insulating film (dielectric film) is deposited in the hole 42 in which the lower electrode 43a is formed and deposited on the silicon oxide film 41. The tantalum oxide film 44 can be formed by, for example, the CVD method using Ta (OC₂H₅)₅ and O₂ as a material, and the thickness of the film 44 is set to about 10 nm. In this case, the tantalum oxide film deposited by the CVD method is in an amorphous (noncrystalline) state.

Next, a first thermal treatment (annealing) is performed to the tantalum oxide film 44 in an oxidizing atmosphere, for example, in an O₃ (ozone) atmosphere. This first thermal treatment is performed to repair the oxygen defect in the tantalum oxide film 44.

The temperature in the first thermal treatment is needed to satisfy the following conditions: that is, (1) higher than a temperature sufficient to repair the oxygen defect, (2) a temperature having no influence on the materials provided below the tantalum oxide film 44, for example, the lower electrode (Ru film) 43a, the barrier metal film BM, and the plug (polycrystalline silicon film) 39.

The upper and lower limit of the temperature of the first thermal treatment is changed depending on the materials to be used and the atmosphere of the thermal treatment. However, when the Ru film is used as the lower electrode like in this embodiment, it is necessary to perform the thermal treatment at 420° C. or lower in an ozone atmosphere. In addition, it is necessary to perform the thermal treatment at 300° C. or higher in an ozone atmosphere to repair the oxygen defect of the tantalum oxide film.

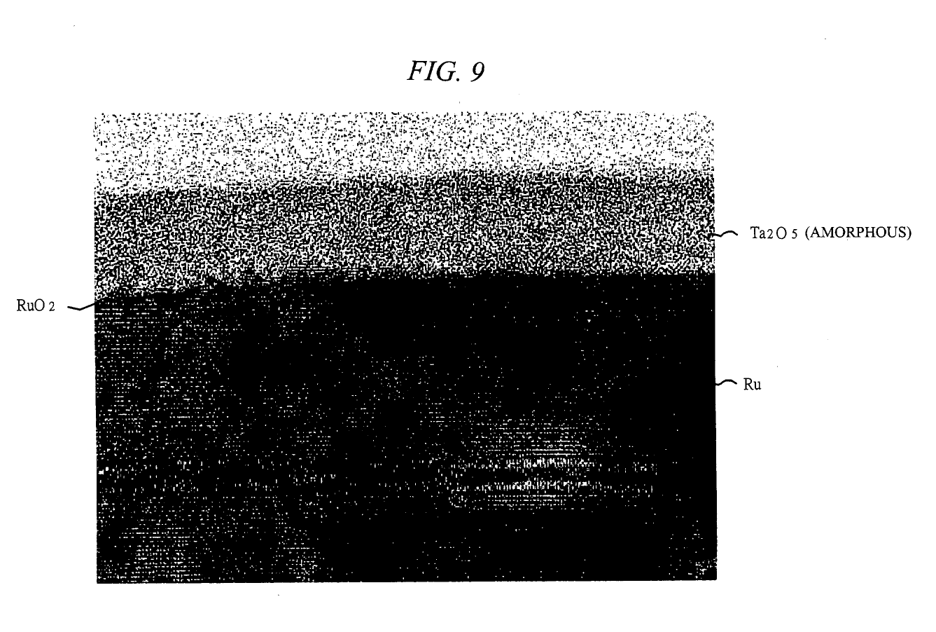

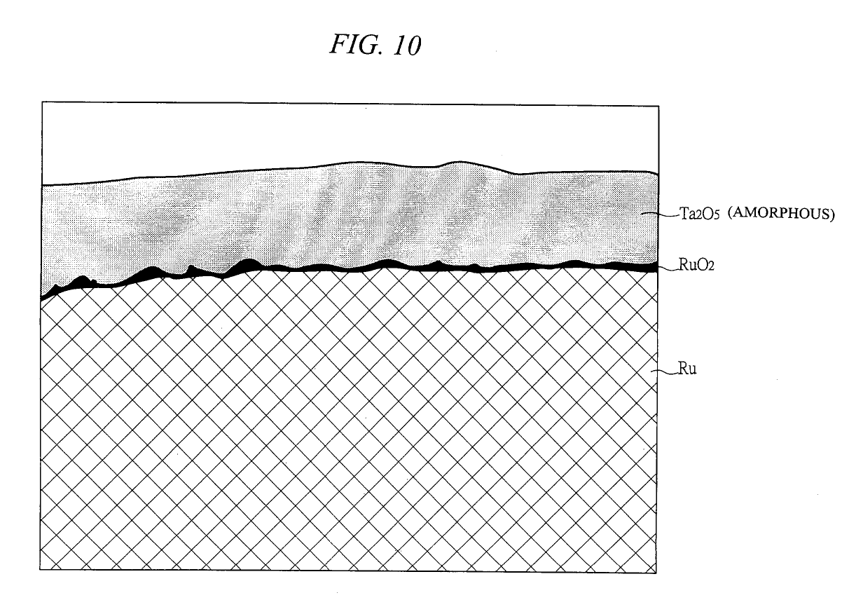

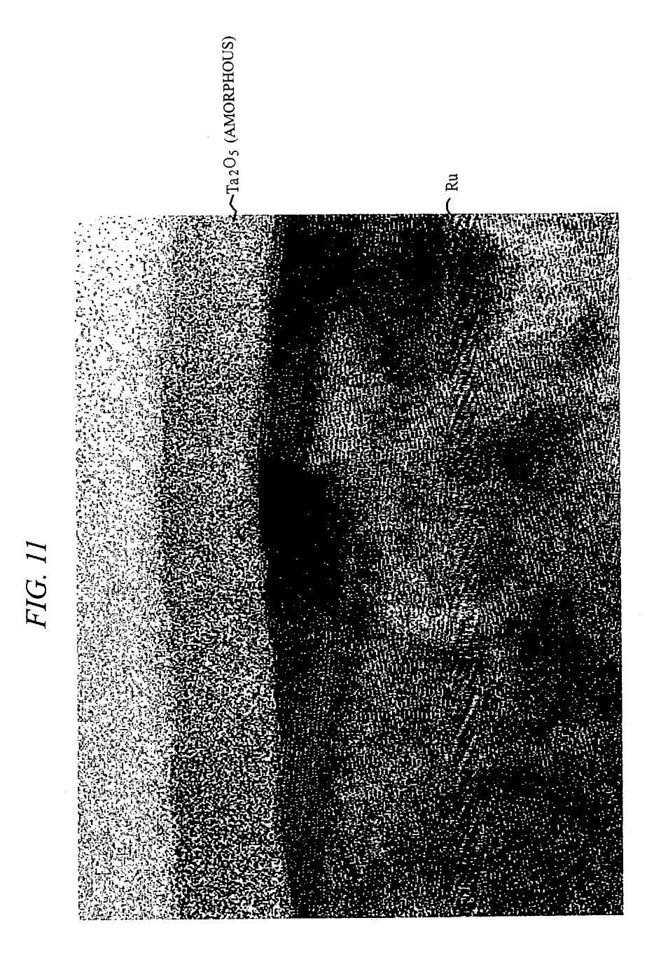

FIG. 9 is a photograph showing the state of a film in the case where a thermal treatment is performed to the laminated film of the Ru film and the tantalum oxide (Ta₂O₅) film at 500° C. in an ozone atmosphere. FIG. 10 schematically shows the state of the film in FIG. 9. Note that the tantalum oxide (Ta₂O₅) film in FIG. 9 and later-described FIG. 11 is in an amorphous state.

As shown in FIGS. 9 and 10, in the case where the thermal treatment is performed at 500° C. in an ozone atmosphere, a ruthenium oxide (RuO₂) film is formed at the interface between the Ru film and the tantalum oxide film. The formation of such a film causes the deterioration of the characteristics of the data storage capacitor C, for example, decrease of the capacitance and increase of the leakage current (due to the deformation in the Ta₂O₅ film).

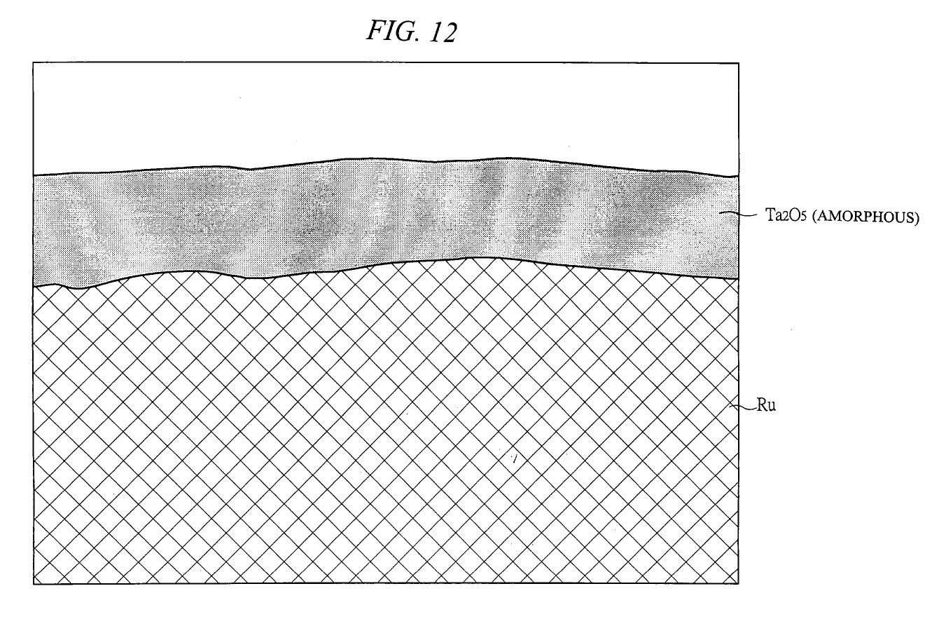

Meanwhile, as shown in FIGS. 11 and 12, in the case where the thermal treatment is performed at 400° C. in an ozone atmosphere, a ruthenium oxide (RuO₂) film at the interface between the Ru film and the tantalum oxide (Ta₂O₅) film is not observed. FIG. 11 is a photograph showing the state of a film in the case where a thermal treatment at 400° C. in an ozone atmosphere is performed to the laminated film of the Ru film and the tantalum oxide film. FIG. 12 schematically shows the state of the film in FIG. 11.

As described above, according to this embodiment, since the first thermal treatment in an ozone atmosphere at 300 to 400° C. is performed to the tantalum oxide film on the Ru film, it is possible to repair the oxygen defect in the tantalum oxide, and it is also possible to prevent the formation of the oxide at the interface between the materials provided below the tantalum oxide film (for example, at the interface between the Ru film and the tantalum oxide film, between the barrier metal film and the lower electrode, and between the barrier metal film and the plug). Alternatively, it is possible to reduce the thickness of the oxide film formed at these interfaces, for example, to reduce the thickness of the oxide film formed at these interfaces to less than one-tenth of that of the tantalum oxide film.

Note that, in the case where it is intended to repair the oxygen defect in the tantalum oxide film by the thermal treatment in the oxygen (O₂) atmosphere, the thermal treatment must be performed at the temperature of 600° C. or higher. Therefore, there is no temperature range preferable to perform the first thermal treatment in the oxygen atmosphere in the case of using the Ru film as the lower electrode. Accordingly, when using the Ru film as the lower electrode, it is preferable to perform the first thermal treatment to the tantalum oxide film provided on the Ru film in an ozone atmosphere. Also, in the case where materials other than Ru such as Pt (platinum) described above are used as the lower electrode, the thermal treatment in the oxygen (O₂) atmosphere may be performed.

Next, a second thermal treatment (annealing) is performed to the tantalum oxide film 44 in an inactive atmosphere, for example, N₂ (nitrogen) atmosphere. This second thermal treatment rearranges the crystal constituting the tantalum oxide film 44.

The important thing here is to prevent the complete crystallization of the tantalum oxide film 44. Therefore, after the second thermal treatment, the phase of the tantalum oxide film is changed and the tantalum oxide film has a microcrystalline structure. However, it is not completely crystallized.

The complete crystallization mentioned here indicates the state in which the crystal grain is not enlarged and is not moved even if the thermal treatment at higher temperature (675° C. or higher) is applied. The crystallization like this occurs at the temperature of 675° C. (transition temperature of the crystal of the tantalum oxide film) or higher. Also, when the crystallization is advanced, the dielectric constant of the tantalum oxide film becomes more than 60.

Note that the tantalum oxide film after the second thermal treatment can be in an amorphous state instead of the microcrystalline state.

The upper and lower limit of the temperature of the second thermal treatment is changed depending on the materials to be used. However, when the tantalum oxide film is used like in this embodiment, it is necessary to perform the thermal treatment at a temperature (675° C. or lower) in which the tantalum oxide film is not completely crystallized.

The reason why the incomplete crystallization of the tantalum oxide film is necessary as described above will be described below.

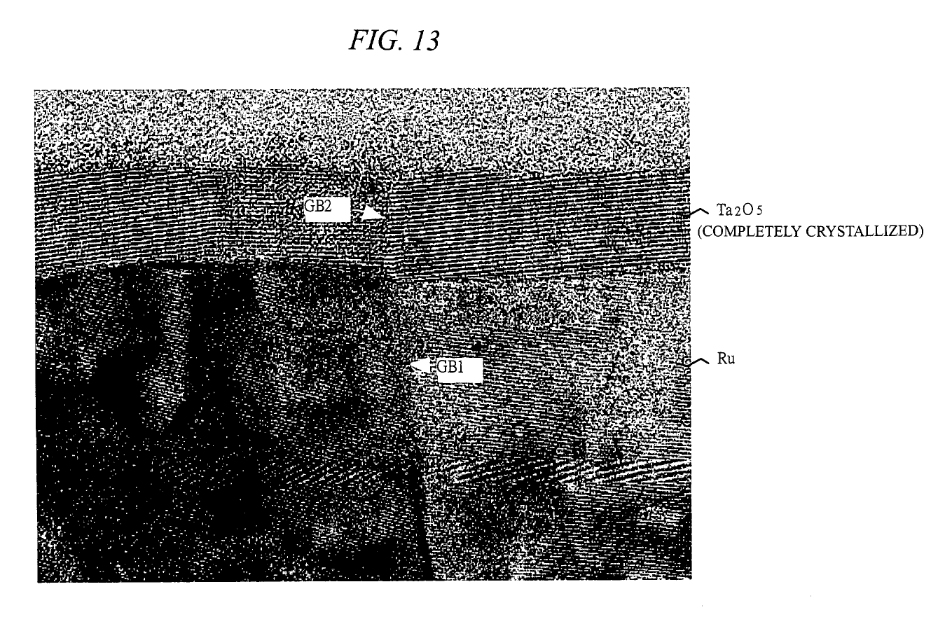

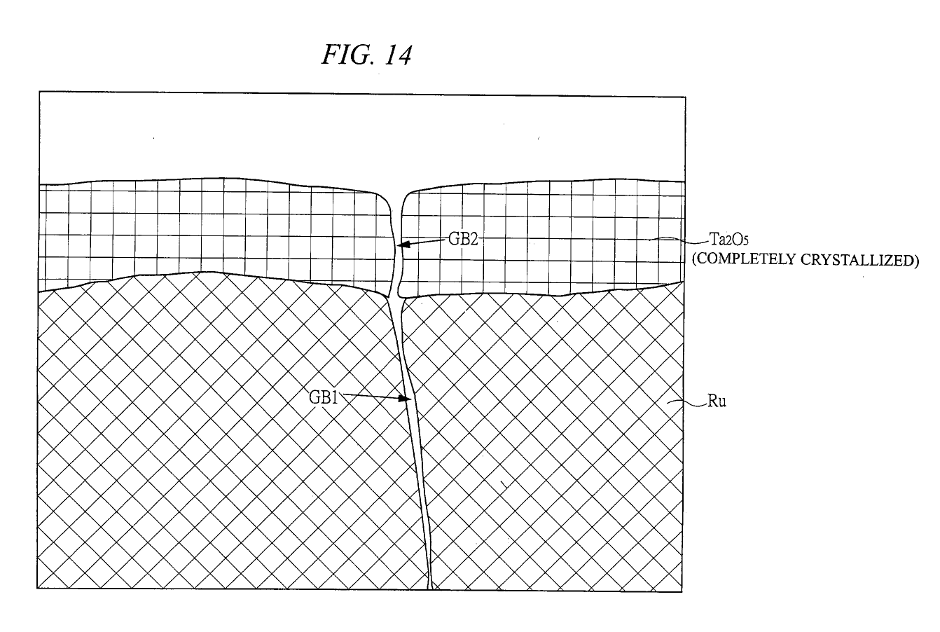

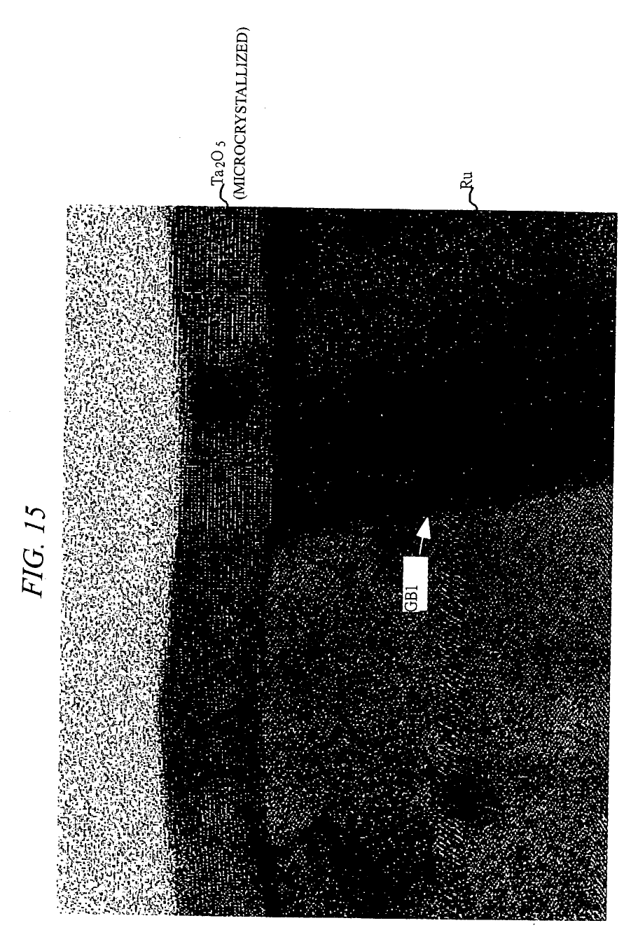

FIG. 13 is a photograph showing a state of the laminated film of the Ru film and the tantalum oxide (Ta₂O₅) film to which the first thermal treatment in the ozone atmosphere at 400° C. and the subsequent second thermal treatment in the nitrogen atmosphere at 700° C. have been performed. FIG. 14 schematically shows the state of the film in FIG. 13.

As shown in FIGS. 13 and 14, a grain boundary GB1 of Ru exists in the Ru film constituting the lower electrode. In the case where the second thermal treatment in the nitrogen atmosphere at 700° C. is performed to the tantalum oxide film on the Ru film in which the grain boundary GB1 exists as described above and the tantalum oxide film is completely crystallized, a grain boundary GB2 of tantalum oxide extending from the grain boundary GB1 in the Ru film is formed. In this case, the grain boundary GB2 is formed so as to penetrate the tantalum oxide film. The formation of the grain boundary GB2 causes the problems of the increase of the leakage current flowing from the lower electrode to the upper electrode through the tantalum oxide film. As a result, the data retention characteristics of the DRAM memory cell are deteriorated.

As described above, it is believed that the reason why the grain boundary GB2 is formed is that the crystallization of the tantalum oxide film proceeds with the orientation along with that of the crystal of the Ru film provided below it. More specifically, the crystal of the tantalum oxide film is grown on the crystal of Ru, however, the crystal of the tantalum oxide film is difficult to grow on the grain boundary of the Ru film. As a result, the grain boundary GB2 of the tantalum oxide film is formed on the grain boundary GB1 of the Ru film.

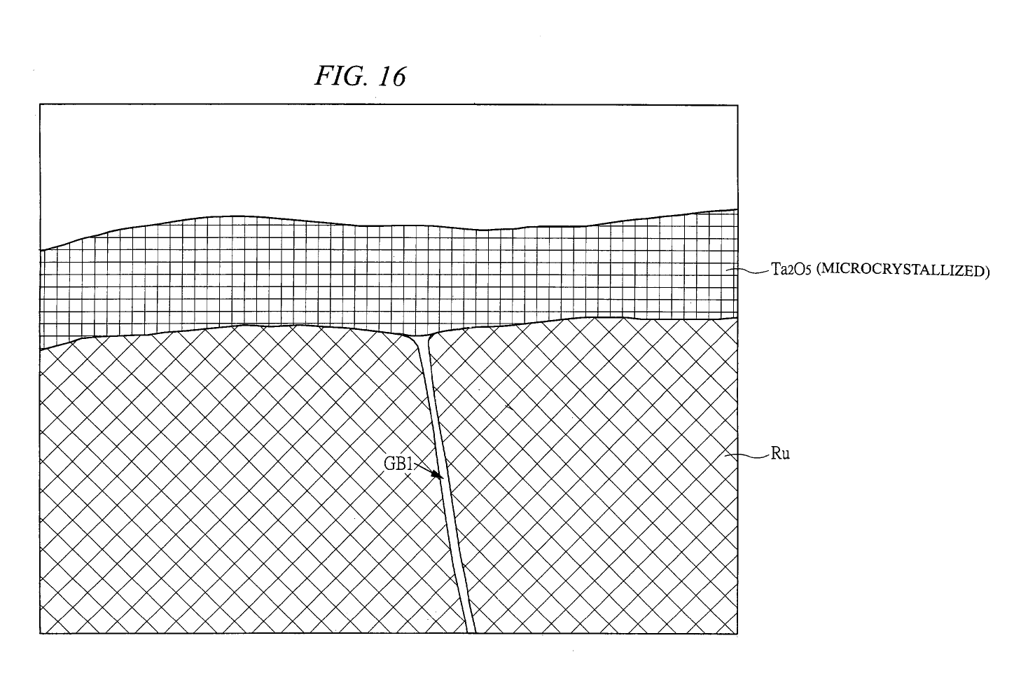

Meanwhile, as shown in FIGS. 15 and 16, in the case where the first thermal treatment is performed to the laminated film of the Ru film and the tantalum oxide (Ta₂O₅) film in an ozone atmosphere at 400° C. and then the second thermal treatment is performed in a nitrogen atmosphere at 600° C., the tantalum oxide film is not completely crystallized, that is, in a microcrystalline state. Therefore, the grain boundary is not observed in the tantalum oxide film. Note that FIG. 15 is a photograph showing a state of the laminated film of the Ru film and the tantalum oxide film to which the first thermal treatment in the ozone atmosphere at 400° C. and the subsequent second thermal treatment in the nitrogen atmosphere at 600° C. have been performed. FIG. 16 schematically shows the state of the film in FIG. 15.

As described above, according to the first embodiment, since the second thermal treatment is performed to the tantalum oxide film on the Ru film in a nitrogen atmosphere at a temperature not causing the complete crystallization (650° C. or lower), it is possible to prevent or reduce the formation of the grain boundary in the tantalum oxide film. As a result, it is possible to reduce the leakage current flowing through the tantalum oxide film.

Also, the second thermal treatment in an inactive atmosphere performed to the tantalum oxide film 44 is performed at a temperature higher than that applied in the process after the formation of the tantalum oxide film 44.

More specifically, as described later, a plug 53, a wiring 54 and the like are formed on the data storage capacitor. The high temperature in the process of forming the plug 53 and the wiring 54 is about 450° C. at the time of the formation of the W film constituting the plug by the CVD method.

Therefore, the following advantages can be achieved by performing the second thermal treatment at 450° C. or higher.

That is, in the case where the second thermal treatment is performed to the tantalum oxide film at 450° C., the complete crystallization of the tantalum oxide film can be prevented. However, when the thermal load higher than the temperature is applied to the tantalum oxide film in the later process, the crystal grains of the tantalum oxide film are moved and the interfacial state between the tantalum oxide film and the Ru film (lower electrode) below it is deteriorated. For example, the voids are created in the interface and the hillock (protrusion) of the tantalum oxide film is grown in the tantalum oxide film. As a result, the deterioration of the characteristics occurs in the data storage capacitor C, for example, the increase of the leakage current.

Also, since the upper electrode 45c and the silicon oxide film (interlayer insulating film) 50 are already formed over the tantalum oxide film in the process of forming the plug, the interfacial state between the tantalum oxide film and the Ru film (lower electrode) below it is deteriorated due to the change in the film stress of these films.

Contrary to this, in the case where the second thermal treatment is performed in advance at a temperature of 450° C. or higher, the crystal grains of the tantalum oxide film are not moved in the process of forming the plug, and it is possible to maintain the characteristics of the data storage capacitor C. In addition, since the change in the film stress can be reduced, it is possible to maintain the characteristics of the data storage capacitor C.

Note that, in this embodiment, the process of forming a plug is taken as an example of the process performed after the formation of the tantalum oxide film 44. However, it goes without saying that it is necessary to consider not only the temperature in the process of forming a plug but also the temperature (thermal load) applied in the process of forming a conductive film constituting the upper electrode and the temperature in the process of forming an interlayer insulating film (silicon oxide film) and a wiring on the upper electrode.

For example, in the case where a TiN (titanium nitride) film or a laminated film including a TiN film is used as the film constituting the upper electrode (45c) instead of the later-described Ru film, the temperature at the formation of the TiN film by the CVD method is 500° C. Therefore, it is possible in this case to prevent the movement of the crystal grains of the tantalum oxide film by performing the second thermal treatment at 500° C. or higher and to reduce the change in the film stress. Note that, in the case where a CVD-TiN film or a laminated film including the CVD-TIN film is used as a wiring (54, 56 and the like), the same effect can be obtained.

As described above, in this embodiment, since the second thermal treatment is performed to the tantalum oxide film on the Ru film in a nitrogen atmosphere at a temperature not causing the complete crystallization (650° C. or lower) and higher than that applied in the subsequent processes, it is possible to prevent or reduce the formation of the grain boundary in the tantalum oxide film and the movement of the crystal grains of the tantalum oxide film. As a result, it is possible to improve the characteristics of the data storage capacitor C.

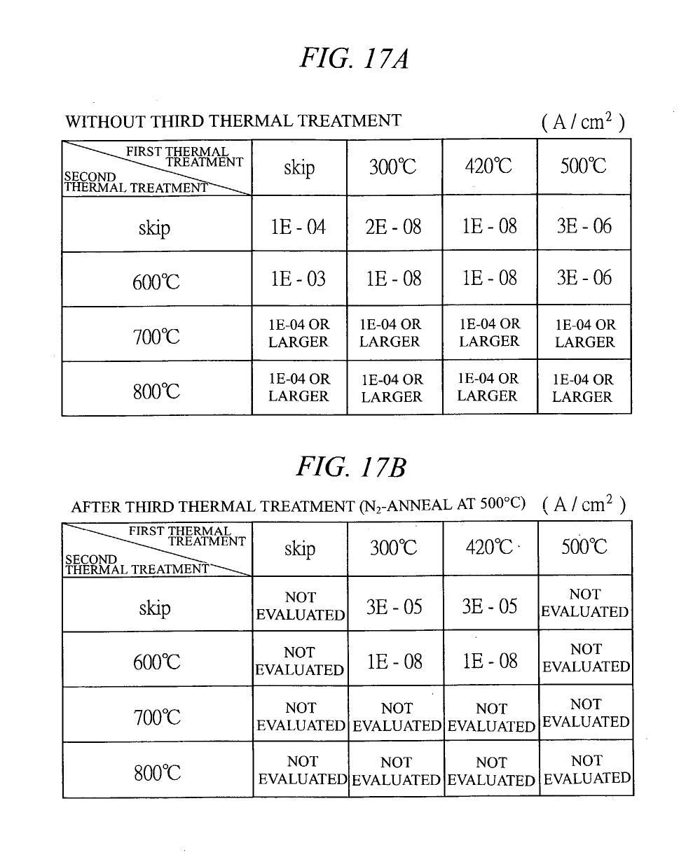

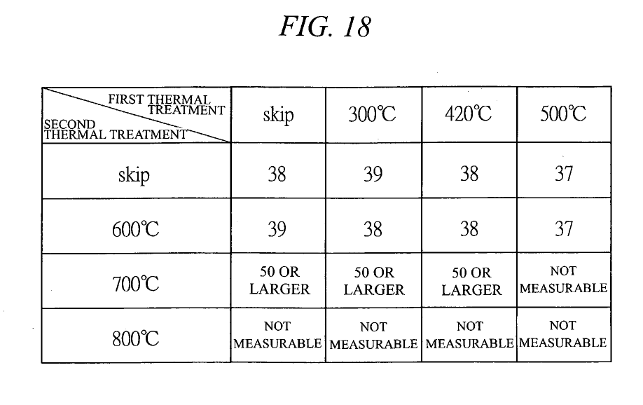

FIG. 17 shows the relationship between the temperatures used in the first thermal treatment (thermal treatment in an oxidizing (O₃) atmosphere) and the second thermal treatment (thermal treatment in an inactive (N₂) atmosphere) and the resultant leakage current. FIG. 17A shows the values of the leakage current before the third thermal treatment (thermal treatment after the formation of the tantalum oxide film), and FIG. 17B shows the values of the leakage current after the third thermal treatment performed in a nitrogen atmosphere at 500° C. In addition, FIG. 18 shows the relationship between the temperatures used in the first and second thermal treatments and the resultant dielectric constant.

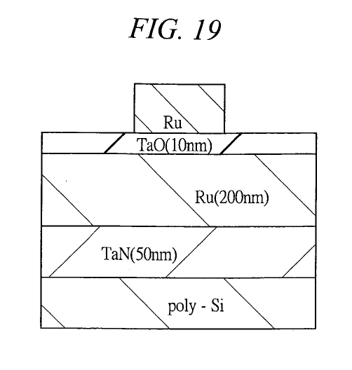

These relationships are evaluated by the use of the TEG (Test Element Group) pattern shown in FIG. 19. More specifically, the leakage current (A/cm²) and the dielectric constant (ε) are measured under the conditions that the pattern as shown in FIG. 19 in which an Ru bump (thickness of 50 nm) as an electrode is formed on a laminated film composed of a polycrystalline silicon (poly-Si) film, a TaN film with a thickness of about 50 nm, an Ru film with a thickness of about 200 nm, and a tantalum oxide (TaO) film with a thickness of about 10 nm is used, the temperature is set to 120° C., and a voltage of about 1V is applied between the Ru electrodes above and below the TaO film. The first and second thermal treatments (either or both of the thermal treatments may not be performed in some cases) are performed to the tantalum oxide (TaO) film. Also, FIG. 17B shows the results after the third thermal treatment is performed.

As shown in FIG. 17A, in the case where the first thermal treatment (thermal treatment in an oxidizing atmosphere) is performed at 420° C. and the second thermal treatment (thermal treatment in an inactive atmosphere) is performed at 600° C., the leakage current is 1×10⁻⁸ (hereinafter, 10⁻ⁿ is represented as e-n) A/cm². Meanwhile, in the case where the first thermal treatment (thermal treatment in an oxidizing atmosphere) is performed at 420° C. and the second thermal treatment (thermal treatment in an inactive atmosphere) is performed at 700° C., the leakage current is increased. That is, the leakage current is increased to 1e-5 (A/cm²) or larger and resulting in the short circuit (dead short circuit: DC). Furthermore, in the case where the first thermal treatment (thermal treatment in an oxidizing atmosphere) is performed at 420° C. and the second thermal treatment (thermal treatment in an inactive atmosphere) is not performed (skip), the leakage current is 1e-8 (A/cm²). However, the leakage current after performing the thermal treatment in a nitrogen atmosphere at 500° C. as the third thermal treatment remains 1e-8 (A/cm²) in the case where the second thermal treatment is performed. Meanwhile, it is increased to 3e-5 (A/cm²) in the case where the second thermal treatment is not performed.

In addition, in FIG. 17A, in the case where the first thermal treatment (thermal treatment in an oxidizing atmosphere) is performed at 500° C. and the second thermal treatment (thermal treatment in an inactive atmosphere) is not performed, the leakage current is 3e-6 (A/cm²).

Meanwhile, as shown in FIG. 18, in the case where the first thermal treatment (thermal treatment in an oxidizing atmosphere) is performed at 420° C. and the second thermal treatment (thermal treatment in an inactive atmosphere) is performed at 600° C., the dielectric constant of the tantalum oxide film is 38. Also, in the case where the first thermal treatment (thermal treatment in an oxidizing atmosphere) is performed at 420° C. and the second thermal treatment (thermal treatment in an inactive atmosphere) is performed at 700° C., the dielectric constant of the tantalum oxide film is 50 or larger. Meanwhile, in the case where the first thermal treatment (thermal treatment in an oxidizing atmosphere) is performed at 420° C. and the second thermal treatment (thermal treatment in an inactive atmosphere) is performed at 800° C., the dielectric constant cannot be measured due to the large leakage current.

As described above, in the case where the first thermal treatment (thermal treatment in an oxidizing atmosphere) is performed at 300 to 420° C. and the second thermal treatment (thermal treatment in an inactive atmosphere) is performed at 600° C., the leakage current of 1e-8 (A/cm²) and the dielectric constant of about 38 can be obtained even after the third thermal treatment.

As described above, according to this embodiment, it is possible to reduce the leakage current to 2e-8 (A/cm²) or smaller.

Next, the method of manufacturing a DRAM after the first and second thermal treatments of the tantalum oxide film will be described.

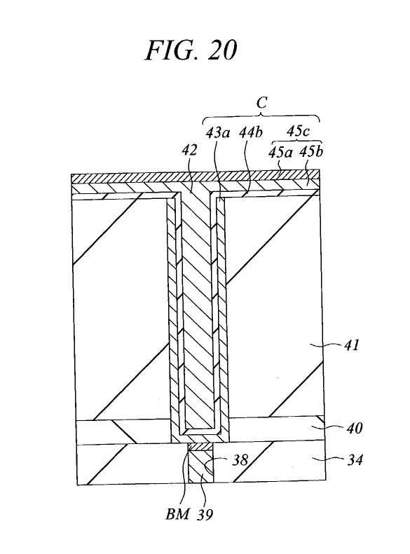

As shown in FIG. 20, the upper electrode 45c is formed over the tantalum oxide film (capacitor insulating film) 44b to which the first and second thermal treatments have been performed. The upper electrode 45c is formed by, for example, depositing an Ru film 45a (with a thickness of about 30 nm) and a W film 45b (with a thickness of about 100 nm) over the tantalum oxide film (capacitor insulating film) 44b by the CVD method. The W film is used to reduce the contact resistance between the upper electrode 45c and the later-described upper layer wiring. Note that it is also possible to form a TiN film between the Ru film and the W film for preventing the increase of the resistance due to the diffusion of gas (oxygen and hydrogen) from the tantalum oxide film (capacitor insulating film) 44b to the W film.

In the process so far, the data storage capacitor C composed of the lower electrode 43a formed of the Ru film 43, the capacitor insulating film 44 formed of the tantalum oxide film, and the upper electrode 45c formed of a laminated film of the Ru film and the W film is completed, and the memory cell of a DRAM composed of the data transfer MISFET Qs and the data storage capacitor C connected in series to the MISFET is almost completed. Note that FIG. 25 is a plan view showing the principal part of the memory cell forming area after the formation of the data storage capacitor C. FIG. 3 and FIG. 20 showing the upper part of FIG. 3 correspond to, for example, the sectional view taken along the line A-A in FIG. 25.

Thereafter, two layers or so of wirings are formed in the memory cell forming area and the peripheral circuit forming area. The process of forming the wirings will be described below.

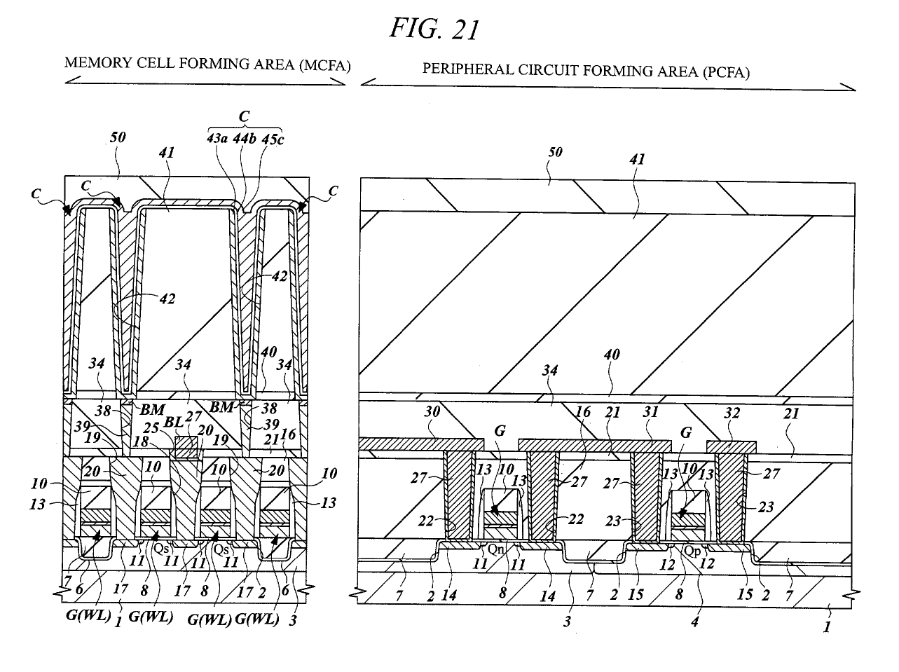

First, as shown in FIG. 21, a silicon oxide film 50 is deposited over the data storage capacitor C by the CVD method. In this case, a thick insulating film composed of the silicon oxide films 34, 41, and 50 and the silicon nitride film 40 is left over the wirings 30 to 32 in the peripheral circuit forming area.

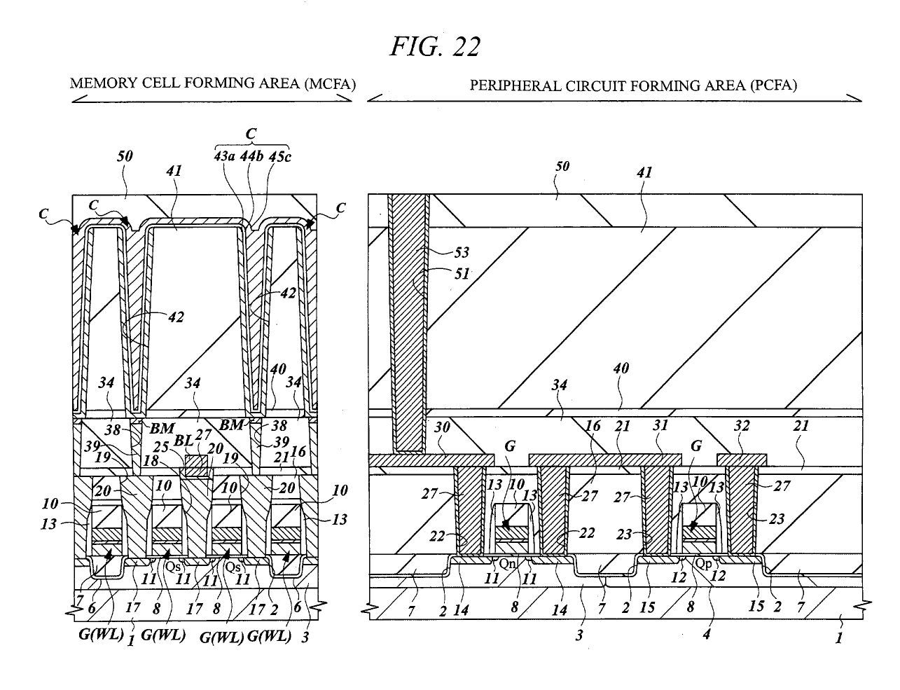

Next, as shown in FIG. 22, the thick insulating film (34, 40, 41, and 50) over the wiring 30 in the peripheral circuit forming area is dry-etched with using a photoresist film (not shown) as a mask, thereby forming a through hole 51. Subsequently, a plug 53 is formed in the through hole 51. The through hole 51 is formed in the following manner. That is, a thin TiN film is deposited on the silicon oxide film 50 by the sputtering method and a W film is deposited thereon by the CVD method. Thereafter, these films are etched back or polished by the CMP method to leave these films in the through hole 51.

In this case, the temperature at the formation of the W film is about 450° C. Since the tantalum oxide film on the Ru film (lower electrode) is subjected to the thermal treatment in a nitrogen atmosphere at 450° C. or higher, it is possible to prevent or reduce the movement of the crystal grains of the tantalum oxide film at the time of the formation of the W film. As a result, it is possible to prevent the deterioration of the interfacial state between the tantalum oxide film and the Ru film (lower electrode) below it and thus to maintain the characteristics of the data storage capacitor C.

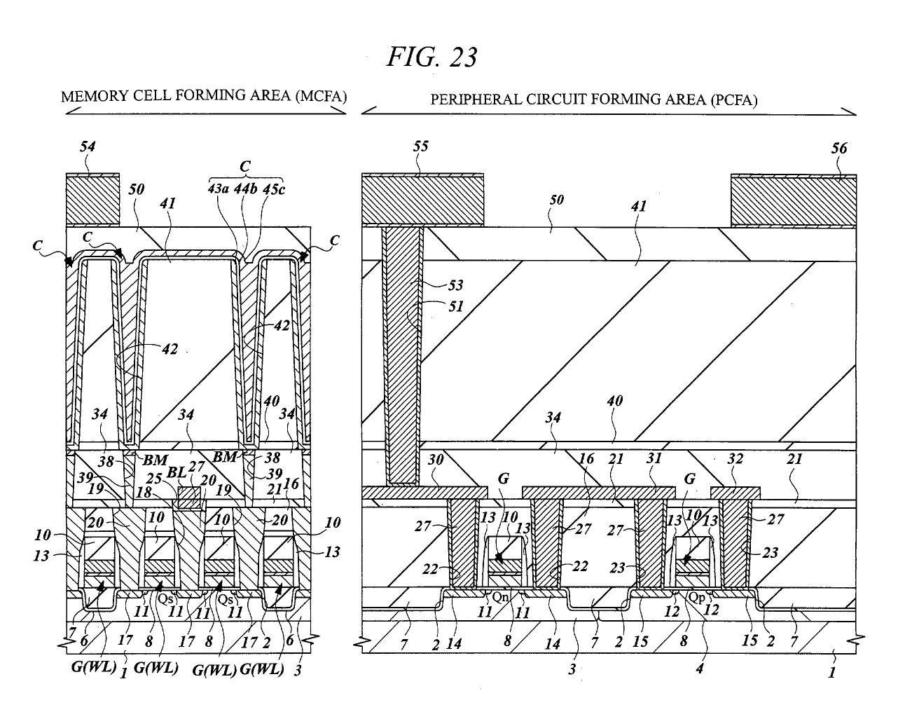

Next, as shown in FIG. 23, wirings 54 to 56 are formed on the silicon oxide film 50. The wirings 54 to 56 are formed in the following manner. First, a thin TiN film, an Al (aluminum) alloy film with a thickness of about 500 nm, and a thin Ti film are deposited on the silicon oxide film 50 by the sputtering method. Note that the temperature at the formation of the Al alloy film is, for example, 400° C.

Subsequently, the laminated film of the TiN film, the Al alloy film, and the Ti film is dry-etched with using a photoresist film (not shown) as a mask, thereby forming the wirings 54 to 56. Note that the plug 53 (not shown in FIG. 23) is formed also below the wiring 54 formed in the memory cell forming area.

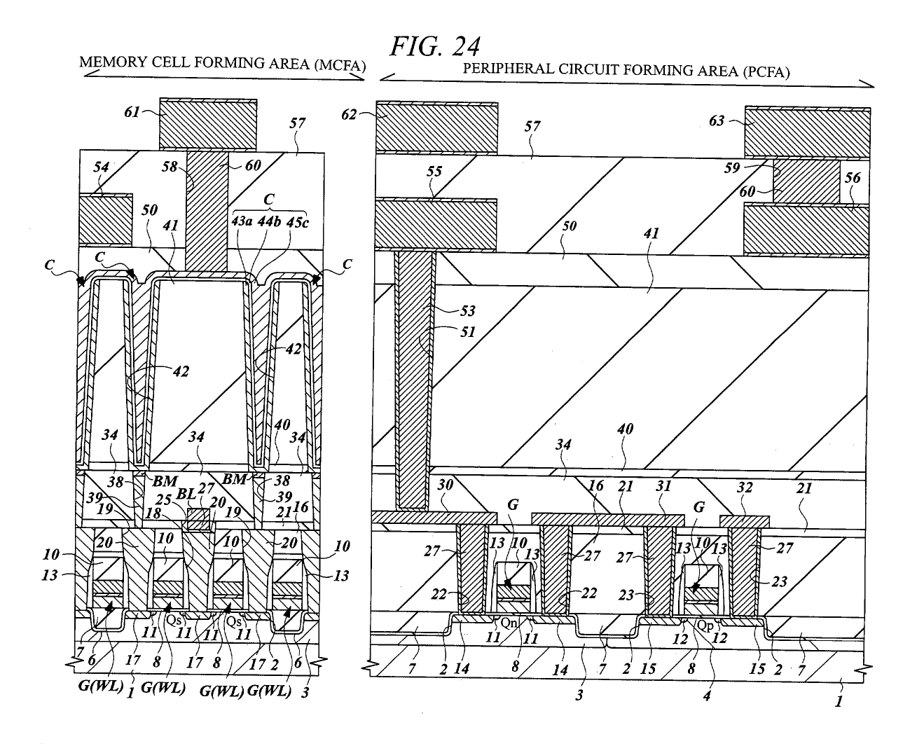

Next, as shown in FIG. 24, a silicon oxide film 57 is formed over the wirings 54 to 56 by the CVD method.

Next, a through hole 58 is formed over the data storage capacitor C with using a photoresist film (not shown) as a mask. In this case, a through hole 59 is also formed on the wiring 56.

Next, plugs 60 are formed in the through holes 58 and 59. The plug 60 is formed in the following manner. That is, a W film (or sputter-TiN film and CVD-W film) is deposited by the CVD method over the silicon oxide film 57 and in the through holes 58 and 59. Thereafter, the film over the silicon oxide film 57 is etched-back or polished by the CMP method to leave the film in the through holes 58 and 59.

In this case, the temperature at the formation of the W film is about 450° C. and the tantalum oxide film is subjected to the thermal treatment in a nitrogen atmosphere at 450° C. or higher as described above. Therefore, it is possible to prevent or reduce the movement of the crystal grains of the tantalum oxide film. As a result, it is possible to maintain the characteristics of the data storage capacitor C.

Subsequently, wirings 61 to 63 are formed on the silicon oxide film 57 and the plug 60. The wirings 61 to 63 are formed in the same manner as that of the wirings 54 to 56. More specifically, a thin TiN film, an Al (aluminum) alloy film with a thickness of about 500 nm, and a thin Ti film are deposited over the silicon oxide film 57 by the sputtering method. Thereafter, these films are dry-etched with using a photoresist film (not shown) as a mask, thereby forming the wirings 61 to 63. Note that the temperature at the formation of the Al alloy film is, for example, 400° C.

Thereafter, a protection film composed of a silicon oxide film and a silicon nitride film is deposited on the wirings 61 to 63. However, the illustration of the film is omitted. In the foregoing process, the DRAM according to this embodiment is almost completed.

Note that this embodiment has been described with taking the nitride atmosphere as an example of the inactive atmosphere. However, an argon (Ar) atmosphere is also available in addition to the nitrogen atmosphere.

Also, in this embodiment, the second thermal treatment performed in an inactive atmosphere is performed after the first thermal treatment performed in an oxidizing atmosphere. However, it is also possible to perform the first thermal treatment after the second thermal treatment.

However, in the case where the tantalum oxide film becomes microcrystalline by the second thermal treatment, the oxygen atoms are difficult to enter the crystal. Therefore, larger effect can be obtained in the case where the second thermal treatment is performed after repairing the oxygen defect by the first thermal treatment in the oxidizing atmosphere.

Also, a tantalum oxide film is used as a capacitor insulating film in this embodiment. However, an STO (SrTiO₃: strontium titanate) film is also available in addition to the tantalum oxide film.

In the case of using the STO film, the preferable temperature range of the first thermal treatment is from 300 to 420° C. because the temperature sufficient to repair the oxygen defect in the ozone atmosphere is 300° C. or higher and the temperature having no influence on the materials provided below the capacitor insulating film, for example, the lower electrode (Ru film) 43a, the barrier metal film BM, and the plug (polycrystalline silicon film) 39 is 420° C. or lower.

Also, assuming that the process after forming the STO film (thermal load) is identical to that in this embodiment, the preferable temperature range of the second thermal treatment is 450° C. or higher. Note that since the temperature at which the STO film is crystallized is 400° C., the STO film is crystallized during its own formation. However, considering the damages on the base of the MISFET, a temperature of about 600° C. is the upper limit.

(Second Embodiment)

In the first embodiment, the barrier metal film BM is formed over the plug 39. However, the barrier metal film BM having the following structure is also available. Note that the method of manufacturing a DRAM according to this embodiment is the same as that in the first embodiment except the process of forming the barrier metal film BM. Therefore, the detail description is omitted.

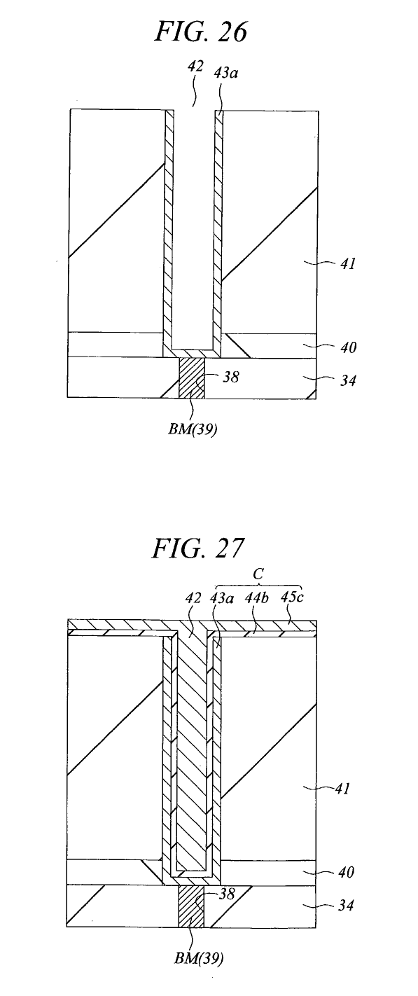

For example, it is also possible to form the barrier metal film BM simultaneously with the formation of the plug 39 by filling the TaN film into the through hole 38 as shown in FIG. 26.

In this case, for example, the silicon oxide film 34 and the silicon oxide film 21 below it in the memory cell forming area are dry-etched, thereby forming a through hole 38 over the plug 20 in the contact hole 19 as described in the first embodiment with reference to FIG. 3.

Next, as shown in FIG. 26, a TaN film is deposited on the silicon oxide film 34 and in the through hole 38 by the sputtering method. Thereafter, the upper surface of the film is polished by the CMP method to leave it only in the through hole 38, thereby forming the plug 39 (barrier metal film BM).

Thereafter, the data storage capacitor C composed of the lower electrode 43a formed of the Ru film 43, the capacitor insulating film (dielectric film) 44b formed of the tantalum oxide film 44, and the upper electrode 45c formed of the laminated film of the Ru film 45a and the W film 45b is formed over the plug 39 in the same manner as that in the first embodiment (FIG. 27). Thereafter, two layers or so of wirings are formed in the memory cell forming area and the peripheral circuit forming area in the same manner as that in the first embodiment.

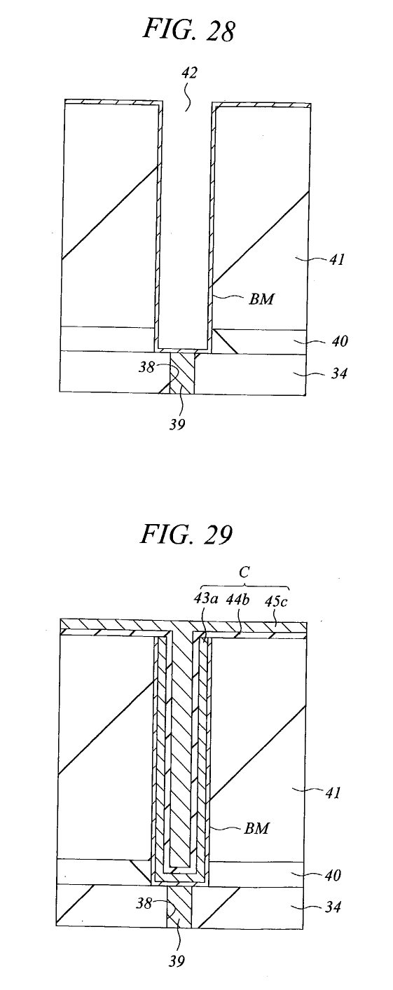

In addition, as shown in FIG. 28, it is also possible to form the barrier metal film BM composed of a TaN film on the sidewall and the bottom surface of the hole 42 in which the data storage capacitor C is to be formed without forming the barrier metal film BM in the upper part of the plug 39.

More specifically, for example, as described in the first embodiment with reference to FIG. 3, the silicon oxide film 34 and the silicon oxide film 21 below it in the memory cell forming area are dry-etched, thereby forming the through hole 38 on the plug 20 in the contact hole 19.

Next, a low-resistance polycrystalline silicon film doped with an n-type impurity (for example, phosphorus) is deposited on the silicon oxide film 34 and in the through hole 38 by the CVD method. Thereafter, the polycrystalline silicon film is polished by the CMP method, thereby forming the plug 39 in the through hole 38.

Subsequently, as shown in FIG. 28, the silicon nitride film 40 with a thickness of about 100 nm is deposited on the silicon oxide film 34 and the plug 39 by the CVD method, and then, the silicon oxide film 41 with a thickness of about 1.4 μm is deposited on the silicon nitride film 40 by the CVD method. Thereafter, a deep hole (concave portion) 42 is formed in these films in the same manner as that in the first embodiment.

Next, a thin TaN film serving as a barrier metal BM is formed on the silicon oxide film 41 and in the hole 42 by the CVD method. Note that the barrier metal film BM outside the hole 42 is removed by the etching. Note that it is also possible to simultaneously etch the barrier metal BM and the Ru film 43 after the formation of the Ru film 43 on the barrier metal BM.

Thereafter, the data storage capacitor C composed of the lower electrode 43a formed of the Ru film 43, the capacitor insulating film (dielectric film) 44b formed of the tantalum oxide film 44, and the upper electrode 45c formed of the laminated film of the Ru film 45a and the W film 45b is formed on the barrier metal film BM in the same manner as that in the first embodiment (FIG. 29). Thereafter, two layers or so of wirings are formed in the memory cell forming area and the peripheral circuit forming area in the same manner that in the first embodiment.

As described above, even though the shape of the barrier metal film BM differs, the oxidation of the surface of the barrier metal film BM can be reduced by performing the thermal treatment of the capacitor insulating film (tantalum oxide film) as described in detail in the first embodiment. Also, it is possible to improve the characteristics of the data storage capacitor C.

In the foregoing, the invention made by the inventors of the present invention has been concretely described based on the embodiments. However, it is needless to say that the present invention is not limited to the foregoing embodiments and various modifications and alterations can be made within the scope of the present invention.

Especially, the DRAM is taken as an example in the descriptions of the foregoing embodiments. However, the present invention can be widely applied to other semiconductor integrated circuit devices having a capacitor in addition to the DRAM.

The advantages achieved by the typical ones of the inventions disclosed in this application will be briefly described as follows.

The first thermal treatment in an oxidizing atmosphere and the second thermal treatment in an inactive atmosphere are performed to a dielectric film of a semiconductor integrated circuit device having a capacitor, and the temperature of the second thermal treatment is set higher than that of the third thermal treatment performed thereafter. Therefore, the characteristics of the capacitor can be improved, and as a result, the characteristics of the semiconductor integrated circuit device having the capacitor can be improved.

In addition, the dielectric film in an amorphous state at the time of the deposition is not completely crystallized even after the thermal treatment. Therefore, it is possible to prevent the formation of the grain boundary, which penetrates the dielectric film. As a result, the characteristics of the capacitor can be improved, and thus, the characteristics of the semiconductor integrated circuit device having the capacitor can be improved.

What is claimed is:

1. A semiconductor integrated circuit device comprising a capacitor comprising a lower electrode, a dielectric film, and an upper electrode,
wherein
(a) a grain boundary of conductive material grains constituting the lower electrode exists in the lower electrode, and
(b) a grain boundary of material grains constituting the dielectric film, which penetrates the dielectric film, does not exist in a part of the dielectric film corresponding to the grain boundary of the lower electrode.

2. A semiconductor integrated circuit device comprising a capacitor comprising a lower electrode, a dielectric film, and an upper electrode,
wherein
(a) a grain boundary of conductive material grains constituting the lower electrode exists in the lower electrode, and
(b) a grain boundary of material grains constituting the dielectric film, which extends from an edge portion of the grain boundary in the lower electrode, does not exist in the dielectric film.

3. The semiconductor integrated circuit device according to claim 1,
wherein the lower electrode of the capacitor is electrically connected to a source region and a drain region of a MISFET formed over a main surface of a semiconductor substrate.

4. The semiconductor integrated circuit device according to claim 1,
wherein a conductive film made of metal or metal compound contacts to a lower portion of the lower electrode of the capacitor.

5. The semiconductor integrated circuit device according to claim 1,
wherein the dielectric film is made of tantalum oxide (Ta₂O₅).

6. The semiconductor integrated circuit device according to claim 5,
wherein a leakage current flowing through the dielectric film made of tantalum oxide is 2×10⁻⁸ A/cm² or smaller in the case where a voltage of 1 V is applied between the lower and upper electrodes of the capacitor.

7. The semiconductor integrated circuit device according to claim 5,
wherein a leakage current flowing through the dielectric film made of tantalum oxide is 2×10⁻⁸ A/cm² or smaller in the case where a voltage of 1 V is applied between the lower and upper electrodes of the capacitor under a temperature of 120° C.

8. The semiconductor integrated circuit device according to claim 5,
wherein a dielectric constant of the dielectric film made of tantalum oxide is 50 or smaller.

9. The semiconductor integrated circuit device according to claim 5,
wherein a dielectric constant of the dielectric film made of tantalum oxide is 30 to 50.

10. The semiconductor integrated circuit device according to claim 1,
wherein the lower electrode is made of ruthenium (Ru).

11. The semiconductor integrated circuit device according to claim 1,
wherein the upper electrode is made of ruthenium (Ru).

12. The semiconductor integrated circuit device according to claim 1,
wherein a wiring is formed over the capacitor via an insulating film.

13. A semiconductor integrated circuit device comprising a capacitor comprising a lower electrode, a dielectric film, and an upper electrode,
wherein
(a) a grain boundary of conductive material grains constituting the lower electrode exists in the lower electrode,
(b) the dielectric film is made of tantalum oxide and a grain boundary of material grains constituting the dielectric film, which penetrates the dielectric film, does not exist in a part of the dielectric film corresponding to the grain boundary of the lower electrode, and
(c) a leakage current flowing through the dielectric film made of tantalum oxide is 2×10⁻⁸ A/cm² or smaller in the case where a voltage of 1 V is applied between the lower and upper electrodes of the capacitor under a temperature of 120° C.

14. A semiconductor integrated circuit device comprising a capacitor comprising a lower electrode, a dielectric film made from a tantalum oxide film, and an upper electrode,
wherein
(a) a grain boundary of conductive material grains constituting the lower electrode exists in the lower electrode, and
(b) a tantalum oxide film with a microcrystalline structure exists in the tantalum oxide film on a position corresponding to that of the grain boundary in the lower electrode.

15. A semiconductor integrated circuit device comprising a capacitor comprising a lower electrode, a dielectric film made from a tantalum oxide film, and an upper electrode,
wherein
(a) a grain boundary of conductive material grains constituting the lower electrode exists in the lower electrode, and
(b) a tantalum oxide film with a completely crystallized structure does not exist in the tantalum oxide film on a position corresponding to that of the grain boundary in the lower electrode.

16. The semiconductor integrated circuit device according to claim 5,
wherein the lower electrode is made of ruthenium, and
a ruthenium oxide (RuO) film with a thickness larger than one-tenth of that of the dielectric film is not formed at the interface between the lower electrode and the dielectric film.

17. The semiconductor integrated circuit device according to claim 5,
wherein a conductive film made of metal or metal compound contacts to the lower portion of the lower electrode of the capacitor,
the lower electrode is made of ruthenium, and
an oxide film with a thickness larger than one-tenth of that of the dielectric film is not formed at the interface between the lower electrode and the conductive film.

18. A method of manufacturing a semiconductor integrated circuit device comprising a capacitor comprising a lower electrode, a dielectric film, and an upper electrode,
the method comprising the steps of:
(a) forming a lower electrode;
(b) forming a dielectric film on the lower electrode;
(c) performing a first thermal treatment to the dielectric film in an oxidizing atmosphere;
(d) performing a second thermal treatment to the dielectric film in an inactive atmosphere;
(e) forming an upper electrode on the dielectric film; and
(f) after the step (d), performing a third thermal treatment.

19. The method of manufacturing a semiconductor integrated circuit device according to claim 18,
wherein the step (d) is performed after the step (c).

20. The method of manufacturing a semiconductor integrated circuit device according to claim 18,
wherein the third thermal treatment in the step (f) is a thermal load caused when forming a wiring over the upper electrode via an insulating film.

21. The method of manufacturing a semiconductor integrated circuit device according to claim 18,
wherein the semiconductor integrated circuit device has a MISFET connected in series to the capacitor, and
the method of manufacturing the same includes the step of forming the MISFET over a main surface of a semiconductor substrate before the step (a).

22. The method of manufacturing a semiconductor integrated circuit device according to claim 18,
wherein a temperature in the second thermal treatment in the step (d) is higher than that in the third thermal treatment in the step (f).

23. The method of manufacturing a semiconductor integrated circuit device according to claim 18,
wherein the method further comprises the step of forming a conductive film made of metal or metal compound before the step (a), and
the lower electrode in the step (a) is formed on the conductive film.

24. The method of manufacturing a semiconductor integrated circuit device according to claim 18,
wherein the lower electrode in the step (a) is made of ruthenium (Ru).

25. The method of manufacturing a semiconductor integrated circuit device according to claim 18,
wherein the dielectric film in the step (b) is made from a tantalum oxide (Ta₂O₅) film.

26. The method of manufacturing a semiconductor integrated circuit device according to claim 18,
wherein the dielectric film in the step (b) is made from a tantalum oxide (Ta₂O₅) film and is in an amorphous state at the time of the deposition thereof.

27. The method of manufacturing a semiconductor integrated circuit device according to claim 18,
wherein the dielectric film in the step (b) is made from a tantalum oxide (Ta₂O₅) film, and
the tantalum oxide film after the step (f) is not completely crystallized.

28. The method of manufacturing a semiconductor integrated circuit device according to claim 18,
wherein crystal phase constituting the dielectric film in the step (b) is changed after the second thermal treatment in the step (d).

29. The method of manufacturing a semiconductor integrated circuit device according to claim 18,
wherein the first thermal treatment in the step (c) is performed in an atmosphere containing ozone (03).

30. The method of manufacturing a semiconductor integrated circuit device according to claim 18,
wherein the second thermal treatment in the step (d) is performed in a nitrogen (N₂) atmosphere.

31. The method of manufacturing a semiconductor integrated circuit device according to claim 18,
wherein the first thermal treatment in the step (c) is performed at a temperature of 250 to 420° C.

32. The method of manufacturing a semiconductor integrated circuit device according to claim 18,
wherein the second thermal treatment in the step (d) is performed at a temperature of 450 to 650° C.

33. The method of manufacturing a semiconductor integrated circuit device according to claim 18,
wherein the third thermal treatment in the step (f) is performed at a temperature of 450° C. or lower.

34. A method of manufacturing a semiconductor integrated circuit device comprising a capacitor comprising a lower electrode, a tantalum oxide film, and an upper electrode, the method comprising the steps of:
(a) forming a lower electrode;
(b) forming an amorphous tantalum oxide film on the lower electrode;
(c) performing a first thermal treatment at 250 to 420° C. to the tantalum oxide film in an ozone atmosphere;
(d) performing a second thermal treatment at 450 to 650° C. to the tantalum oxide film in a nitrogen atmosphere;
(e) forming an upper electrode having an Ru (ruthenium) film on the tantalum oxide film; and
(f) after the step (d), performing a third thermal treatment at a temperature 450° C. or lower.

35. A method of manufacturing a semiconductor integrated circuit device comprising a capacitor composed of a lower electrode, a tantalum oxide film, and an upper electrode,
the method comprising the steps of:
(a) forming a lower electrode;
(b) forming an amorphous tantalum oxide film on the lower electrode;
(c) performing a first thermal treatment at 250 to 420° C. to the tantalum oxide film in an ozone atmosphere;
(d) performing a second thermal treatment at 500 to 650° C. to the tantalum oxide film in a nitrogen atmosphere; and
(e) forming an upper electrode having a TiN film (titanium nitride film) on the tantalum oxide film at a temperature of 500° C. or lower.
